(19) United States
(12) Patent Application Publication
(10) Pub. No.: US 2023/0024644 A1
(43) Pub. Date: Jan. 26, 2023

(54) LASER TREATMENT DEVICE AND LASER TREATMENT METHOD

(71) Applicant: Aledia, Echirolles (FR)

(72) Inventor: Tiphaine Dupont, Grenoble (FR)

(73) Assignee: Aledia, Echirolles (FR)

(21) Appl. No.: 17/787,907

(22) PCT Filed: Dec. 22, 2020
(86) PCT No.: PCT/EP2020/087725

§ 371 Date: Jun. 21, 2022

(30) Foreign Application Priority Data
Dec. 26, 2019 (FR) 1915604

(51) Int. Cl. B23K 26/18; B23K 26/57; B23K 26/064

(52) U.S. Cl. CPC B23K 26/18; B23K 26/57; B23K 26/064

(57) ABSTRACT

A device configured for a laser treatment, including a support and objects, each attached to the support via a region absorbing for the laser, the support comprising a system for optically guiding (42, 44, 50, 52) the laser towards at least a plurality of said absorbing regions.

The present patent application claims the priority benefit of French patent application FR19/15604 which is herein incorporated by reference.

### TECHNICAL BACKGROUND

The present disclosure generally concerns laser treatment devices and laser treatment methods of such devices.

### PRIOR ART

For certain applications, it is desirable to be able to transfer objects, for example, optoelectronic circuits, present on an initial support onto a final support. It is known to provide an absorbing layer between each object and the initial support and to focus a laser beam onto each absorbing layer through the initial support, the ablation of the absorbing layer causing the detaching of the object from the initial support.

FIG. 1 is a partial simplified cross-section view which illustrates an example of laser treatment of a device 20 by a treatment system 10.

Treatment system 10 comprises a laser source 12 and an optical focusing device 14 having an optical axis D. Source 12 is configured to deliver an incident laser beam 16 to focusing device 14, which delivers a converging laser beam 18. Preferably, incident laser beam 16 is substantially collimated along the optical axis D of optical device 14.

Device 20 comprises a support 22 substantially transparent to the laser and comprising two opposite surfaces 24 and 26, generally parallel and planar. Laser beam 18 penetrates into support 22 through surface 24. Device 20 comprises absorbing regions 28 on surface 26 and objects 30 to be detached, attached to absorbing regions 28 on the side of absorbing regions 28 opposite to support 22, three objects 30 and three absorbing regions 28 being shown as an example in FIG. 1.

The treatment method may comprise the relative displacement between treatment system 10 and support 22 so that laser beam 18 entirely scans each absorbing region 28, causing the ablation of absorbing regions 28 and the separation of objects 30 from support 22. During the treatment, optical axis D is preferably perpendicular to surface 24.

A disadvantage of the previously-described laser treatment method is that, for each object 30 to be detached, a proper positioning of laser beam 18 with respect to support 22 is necessary to obtain the focusing of laser beam 18 on the absorbing region 28 associated with object 30. Another disadvantage is that the detaching of all the objects 30 being successive, the total duration to detach all the objects 30 may be significant. Another disadvantage is that each object 30 to be detached is located in the line of sight D of laser beam 18. There thus exists a risk, in the case where absorbing region 28 however lets pass a portion of the laser beam, of deterioration of object 30.

### SUMMARY OF THE INVENTION

Thus, an object of an embodiment is to at least partly overcome the disadvantages of the previously-described laser treatment devices and the previously-described laser treatment methods using such devices.

An object of an embodiment is for a plurality of objects to be able to be simultaneously detached.

Another object of an embodiment is for the areas close to the area destroyed by the laser beam not to be damaged by the treatment.

An embodiment provides a device configured for a laser treatment, comprising a support and objects, each attached to the support via a region absorbing for the laser, the support comprising a system for optically guiding the laser towards at least a plurality of said absorbing regions.

According to an embodiment, the optical guiding system comprises a surface optical coupler, adapted to capturing the laser.

According to an embodiment, the optical guiding system comprises a first waveguide for the laser and second waveguides for the laser, each second waveguide extending in front of one of the absorbing regions and being coupled to the first waveguide by an optical waveguide coupler.

According to an embodiment, the surface optical coupler is coupled to an end of the first waveguide.

According to an embodiment, each optical waveguide coupler is a multimode interference coupler or an evanescent wave optical coupler.

According to an embodiment, each optical waveguide coupler comprises a ring microresonator.

According to an embodiment, the optical waveguide couplers comprise at least first optical couplers configured to perform a coupling of a laser radiation at a first wavelength and not to perform a coupling of a laser radiation at a second wavelength different from the first wavelength and second optical couplers configured to perform a coupling of the laser radiation at the second wavelength and not to perform a coupling of a laser radiation at the first wavelength.

According to an embodiment, a plurality of the optical waveguide couplers each have a coefficient of coupling with the first waveguide which depends on temperature.

According to an embodiment, the device further comprises systems for heating said plurality of optical waveguide couplers.

According to an embodiment, the device further comprises a photonic crystal between each object and one of the second waveguides.

According to an embodiment, the photonic crystal is a two-dimensional photonic crystal.

According to an embodiment, the photonic crystal comprises a base layer made of a first material and a grating of pillars made of a second material different from the first material, each pillar extending in the base layer across at least a portion of the thickness of the base layer.

According to an embodiment, each object comprises an electronic circuit.

An embodiment also provides a method of laser treatment of a device comprising a support and objects, each attached to the support via a region absorbing for the laser, the support comprising a system for optically guiding the laser towards at least a plurality of said absorbing regions, the method comprising the exposure to the laser beam of a portion of the optical guiding system.

According to an embodiment, the exposure to the laser beam of a portion of the optical guiding system is performed on the side of the support covered with the objects.

According to an embodiment, the method comprises the attaching of a plurality of objects to a substrate, the objects being still coupled to the support, and the simultaneous destruction of the absorbing regions attached to the objects of said plurality by the laser guided by the optical guiding system.

According to an embodiment, the optical guiding system comprises a first waveguide for the laser and second waveguides for the laser, each second waveguide extending in front of one of the absorbing regions and being coupled to the first waveguide by an optical waveguide coupler having a coefficient of coupling with the first waveguide.

According to an embodiment, each optical waveguide coupler has a coefficient of coupling with the first waveguide, the method comprising a step of modification of the coupling coefficients of a plurality of said optical waveguide couplers to select the objects of said plurality for which is performed the simultaneous destruction of the absorbing regions attached to the objects of said plurality by the laser guided by the optical guiding system.

According to an embodiment, the method comprises a step of heating of said plurality of optical waveguide couplers.

According to an embodiment, the objects are distributed into first objects and second objects, the method comprising, at a first step, the simultaneous destruction of the absorbing regions attached to the first objects by the laser guided by the optical guiding system and, at a second step, the simultaneous destruction of the absorbing regions attached to the second objects by said laser, guided by the optical guiding system.

According to an embodiment, each optical waveguide coupler associated with one of the first objects allows the optical coupling between the first waveguide and the second waveguide coupled to said optical waveguide coupler when the laser is at a first wavelength and does not allow the optical coupling between the first waveguide and the second waveguide coupled to said optical waveguide coupler when the laser is at a second wavelength different from the first wavelength, and each optical waveguide coupler associated with one of the second objects allows the optical coupling between the first waveguide and the second waveguide coupled to said optical waveguide coupler when the laser is at the second wavelength and does not allow the optical coupling between the first waveguide and the second waveguide coupled to said optical waveguide coupler when the laser is at the first wavelength.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1, previously described, illustrates an example of a method of laser treatment of a device;

FIG. 2 is a partial simplified cross-section view of an embodiment of an optoelectronic device intended for a laser treatment;

FIG. 3 is a partial simplified top view of the device shown in FIG. 2;

FIG. 4 is a detail view of an embodiment of a coupler of the device shown in FIGS. 2 and 3;

FIG. 5 shows curves of the variation of optical powers of radiations entering into and coming out of the coupler of FIG. 4 according to a dimension of the coupler;

FIG. 6 is a view similar to FIG. 3 of another embodiment of the device;

FIG. 7 is a view similar to FIG. 3 of another embodiment of the device;

FIG. 8 is a detail view of an embodiment of a coupler of the device shown in FIG. 7;

FIG. 9 shows curves of variation of optical powers of radiations entering into and coming out of the coupler of FIG. 8 according to the wavelength of the incident signal;

FIG. 10 is a view similar to FIG. 3 of another embodiment of the device;

FIG. 11 is a detail view of an embodiment of a coupler of the device shown in FIG. 10;

FIG. 12 shows curves of variation of optical powers of radiations entering into and coming out of the coupler of FIG. 11 according to the wavelength of the incident signal;

FIG. 13 is a view similar to FIG. 3 of another embodiment of the device;

FIG. 14A illustrates a step of an embodiment of a method of manufacturing the device shown in FIGS. 2 and 3;

FIG. 14B illustrates another step of the method;

FIG. 14C illustrates another step of the method;

FIG. 14D illustrates another step of the method;

FIG. 14E illustrates another step of the method;

FIG. 15A illustrates a step of another embodiment of a method of manufacturing the device shown in FIGS. 2 and 3;

FIG. 15B illustrates another step of the method;

FIG. 16 is an enlarged view of an embodiment of the absorbing region of the device of FIGS. 2 and 3;

FIG. 17 is an enlarged view of another embodiment of the absorbing region of the device of FIGS. 2 and 3;

FIG. 18 is an enlarged view of another embodiment of the absorbing region of the device of FIGS. 2 and 3;

FIG. 19 shows an arrangement of the pillars of the photonic crystal layer of the absorbing region of the device of FIGS. 2 and 3; and

FIG. 20 shows another arrangement of the pillars of the photonic crystal layer of the absorbing region of the device of FIGS. 2 and 3.

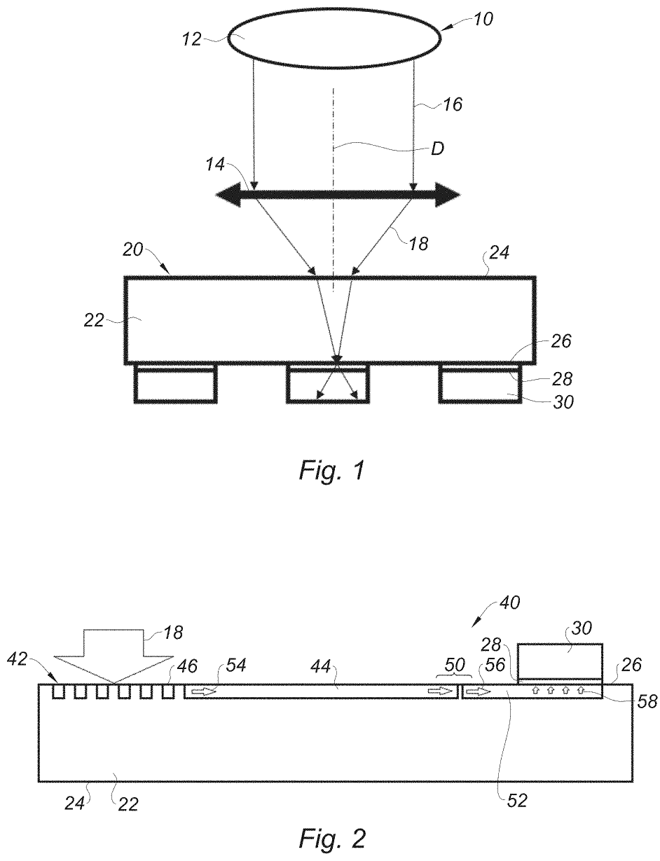

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. In particular, laser sources are well known by those skilled in the art and are not detailed hereafter.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., unless specified otherwise, it is referred to the orientation of the drawings. Unless specified otherwise, the expressions “around”, “approximately”, “substantially” and “in the order of” signify within 10%, and preferably within 5%. Further, it is here considered that the terms “insulating” and “conductive” respectively signify “electrically insulating” and “electrically conductive”.

In the following description, the inner transmittance of a layer corresponds to the ratio of the intensity of the radiation coming out of the layer to the intensity of the radiation entering into the layer. The absorption of the layer is equal to the difference between 1 and the inner transmittance. In the rest of the disclosure, a layer or a film is said to be transparent to a radiation when the absorption of the radiation through the layer or the film is lower than 60%. In the rest of the disclosure, a layer or a film is said to be absorbing to a radiation when the absorption of the radiation through the layer or the film is greater than 60%. In the following description, it is considered that a laser corresponds to a monochromatic radiation. In practice, the laser may have a narrow wavelength range centered on a central wavelength, called wavelength of the laser. In the following description, the refraction index of a material corresponds to the refraction index of the material at the wavelength of the laser used for the laser treatment.

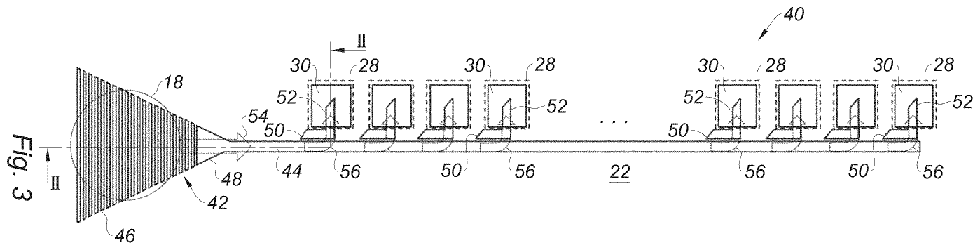

FIGS. 2 and 3 respectively are a cross-section view and a top view, partial and simplified, of an embodiment of a device 40 intended for a laser treatment. FIG. 2 is a cross-section view of FIG. 3 along cross-section plane II-II.

Device 40 comprises all the elements of the previously-described device 20. The view of FIG. 3 is on the side of surface 26. In FIG. 3, the contours of absorbing regions 28 are shown with dotted lines. There has been shown as an example a single object 30 in FIG. 2 and a column of objects 30 in FIG. 3. However, the arrangement of objects 30 on support 22 may be different. As an example, objects 30 may be distributed in rows and in columns. Each object 30 may comprise an electronic circuit, for example, a light-emitting diode circuit, and/or a transistor circuit, particularly with MOS transistors.

According to an embodiment, the thickness of support 22 is in the range from 50 μm to 3 mm. Support 22 may have monolayer structure or a multilayer structure. According to an embodiment, support 22 is made of a semiconductor material. The semiconductor material may be silicon, germanium, or a mixture of at least two of these compounds. According to another embodiment, support 22 is, at least partly, made of a non-semiconductor material, for example, an insulating material, particularly sapphire. According to another embodiment, support 22 has a multilayer structure of silicon-on-insulator type (SOI) and comprises a silicon layer covering an insulating layer, for example, silicon oxide.

According to an embodiment, absorbing region 28 is made of a metal, a metal alloy, a metal nitride, a semiconductor material, or a mixture of at least two of these compounds. Absorbing region 28 is for example made of a refractory metal, particularly titanium (Ti), tungsten (W), molybdenum (Mo), tantalum (Ta), or a mixture or alloy of at least two of these compounds.

According to an embodiment, support 22 comprises, on the side of surface 26, a surface optical coupler 42 coupled to a waveguide 44, called main waveguide hereafter. Surface optical coupler 42 comprises a diffraction grating 46 and, possibly, a tapered guide 48 coupling diffraction grating 46 to waveguide 44.

Device 40 comprises, for a plurality of objects 30 among all the objects 30, preferably for each object 30, an optical coupler 50 between waveguides coupling main waveguide 44 to a waveguide 52, called secondary waveguide hereafter, which extends at least partly under absorbing region 28. According to an embodiment, each optical coupler 50 is a multimode interference coupler or an evanescent wave optical coupler. Each waveguide 50, 52 may have a square or rectangular cross-section, the width of the cross-section of each waveguide 50, 52 measured parallel to surface 26, may be in the range from 100 nm to 1,000 nm, for example, approximately 500 nm. The thickness of each optical element of device 40, measured perpendicularly to surface 26, may be in the range from 100 nm to 1,000 nm.

The optical elements of device 40, in particular surface optical coupler 42, main waveguide 44, couplers 50, and secondary waveguides 52, are formed in a first material having a first refraction index surrounded with a second material having a second refraction index or second materials having second refraction indices, the first refraction index being greater than the second refraction index or than the second refraction indices. The first and second materials are transparent for laser 18. According to an embodiment, the wavelength of laser 18 is in the range from 400 nm to 10 μm, the first material is an oxide, a nitride, a polymer or a semiconductor material, for example, from the family of III-V compounds or of II-V compounds and the second material is air, silicon oxide, and/or silicon nitride. According to an embodiment, the wavelength of laser 18 is in the range from 600 nm to 10 μm, the first material is silicon, and the second material is air, silicon oxide, and/or silicon nitride.

An embodiment of a laser treatment method of device 40 is the following. Laser beam 18, represented by an arrow in FIG. 2 and by a circle in dotted lines in FIG. 3, is focused on the diffraction grating 46 of surface optical coupler 42. Laser radiation 18 is captured by surface optical coupler 42 and guided all the way to the input of main waveguide 44 (which is illustrated by arrow 54). The radiation is then guided in main waveguide 44. At each coupler 50, a portion of the radiation guided in main waveguide 44 is captured by coupler 50 towards the secondary waveguide 52 coupled to coupler 50 (which is illustrated with arrows 56). A portion of the radiation guided in each secondary waveguide 52 is then absorbed in the absorbing region 28 covering secondary waveguide 52 (which is illustrated by arrows 58 in FIG. 2). This causes the ablation of absorbing region 28 and the detaching of the object 30 attached to absorbing region 28 from support 22. To improve the capture of the laser radiation by absorbing region 28, the end of secondary waveguide 52 which extends under absorbing region 28 may have an adapted shape, for example, a flared shape.

Advantageously, laser beam 18 reaches device 40 on the side of surface 26, so that laser beam 18 does not cross the entire thickness of support 22. However, as a variant, laser beam 18 may reach device 40 on the side of surface 24, cross support 22 across its thickness and be captured by diffraction grating 46.

According to an embodiment, support 22 corresponds to the support having at least some of the elements forming objects 30 formed thereon by epitaxy. According to another embodiment, objects 30 are at least partly formed on a support different from support 22 and are transferred onto support 22.

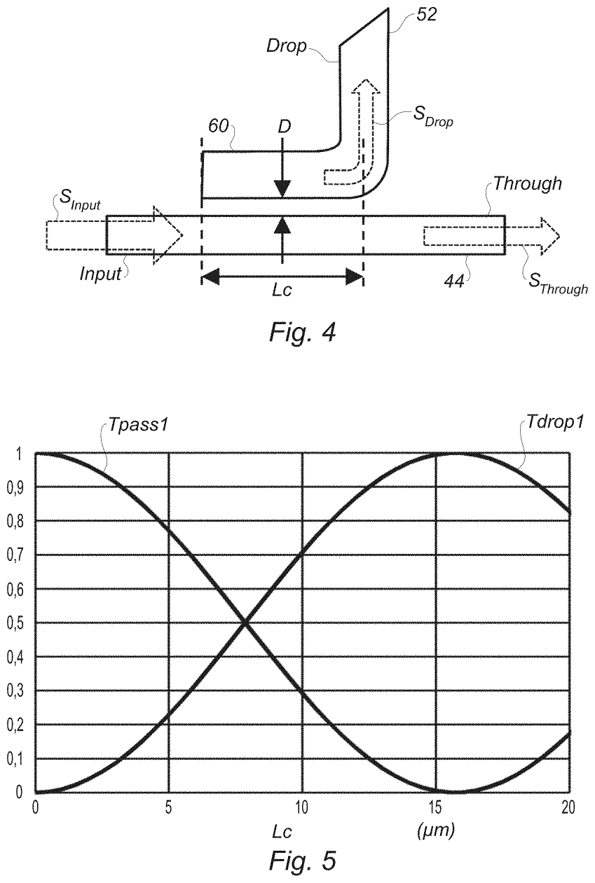

FIG. 4 is a partial simplified top view of one of the couplers 50 shown in FIG. 3. In the rest of the disclosure, generally for any type of coupler 50, call S_{Input} the incident laser radiation arriving at an input Input of coupler 50 via main waveguide 44, S_{Through} the laser radiation which escapes at an output Through of coupler 50 via main waveguide 44, and S_{Drop} the laser radiation which exits at an output Drop coupler 50 via secondary waveguide 52. According to the present embodiment, coupler 50 is a unidirectional-type evanescent wave coupler. Coupler 50 is formed by a portion 60 of secondary waveguide 52 which extends substantially parallel to main waveguide 44 along a coupling length Lc and which is separated from main waveguide 44 by a distance D along the entire coupling length Lc. Coupling length Lc particularly depends on the wavelength of the laser.

FIG. 5 shows a curve of variation Tpass1 according to the coupling length Lc of the ratio of the power of radiation S_{Through} to the power of the incident radiation S_{Input} and a curve of variation Tdrop1 according to coupling length Lc of the ratio of the power of radiation S_{Drop} to the power of radiation S_{Input}. It is thus possible to select the proportion of the incident radiation S_{Input} which is deviated towards secondary waveguide 52.

According to an embodiment, N objects 30 are associated with main waveguide 44, N being an integer, for example, in the range from 2 to 100. Couplers 50 may be substantially identical and each coupler 50 may then be configured so that the ratio of the power of radiation S_{Drop} to the power of incident radiation S_{Input} is substantially equal to 1/n. In this embodiment, the power of the incident laser is substantially equally distributed for the ablation of each absorbing region 28.

According to another embodiment, couplers 50 are distributed into at least a first group of couplers associated with a first laser wavelength λ₁ and a second group of couplers associated with a second laser wavelength λ₂. Each coupler 50 of the first group deviates a portion of the incident radiation at first wavelength λ₁ to the associated secondary waveguide 52 but does not deviate the incident radiation at second wavelength λ₂. Each coupler 50 of the second group deviates a portion of the incident radiation at second wavelength λ₂ to the associated secondary waveguide 52 but does not deviate the incident radiation at first wavelength λ₁. The objects 30 coupled to the couplers 50 of the first group may be detached from support 22 by application of a laser at first wavelength λ₁ while the objects 30 coupled to the couplers 50 of the second group may be detached from support 22 by application of a laser at second wavelength λ₂. Generally, couplers 50 are distributed into M groups of couplers, each group being associated with a first wavelength λᵢ, i varying from 1 to M. Each coupler 50 of the i^{th} group deviates a portion of the incident radiation at wavelength λᵢ towards the associated secondary waveguide 52 but does not deviate the incident radiations at the other wavelengths λⱼ with j different from i. The objects 30 coupled to the couplers 50 of the i^{th} group may be detached from support 22 by application of a laser at wavelength λᵢ.

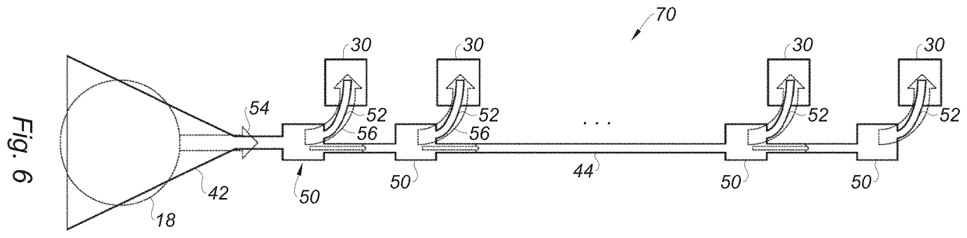

FIG. 6 is a view similar to FIG. 3 of another embodiment of device 70. Device 70 comprises all the elements of device 40 shown in FIGS. 2 and 3, with the difference that each optical coupler 50 is a multimode interference (MMI) coupler. Absorbing regions 28 are not shown in FIG. 6 and surface optical coupler 42 is schematically shown in FIG. 6. Generally, a multimode interference coupler comprises an input monomode guide, a block having a cross-section adapted to a multimode guiding and a plurality of output monomode guides. In the present embodiment, main waveguide 44 corresponds to the input monomode guide of coupler 50 and to a first output monomode guide of coupler 50 and secondary waveguide 52 corresponds to a second output monomode guide of coupler 50. As a variant, each coupler 50 may be a Y coupler.

FIG. 7 is a view similar to FIG. 3 of another embodiment of device 80. Device 80 comprises all the elements of the device 70 shown in FIG. 6, with the difference that each optical coupler 50 is a ring optical microresonator coupler.

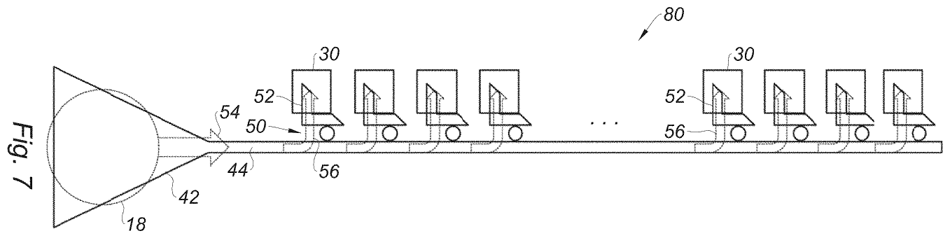

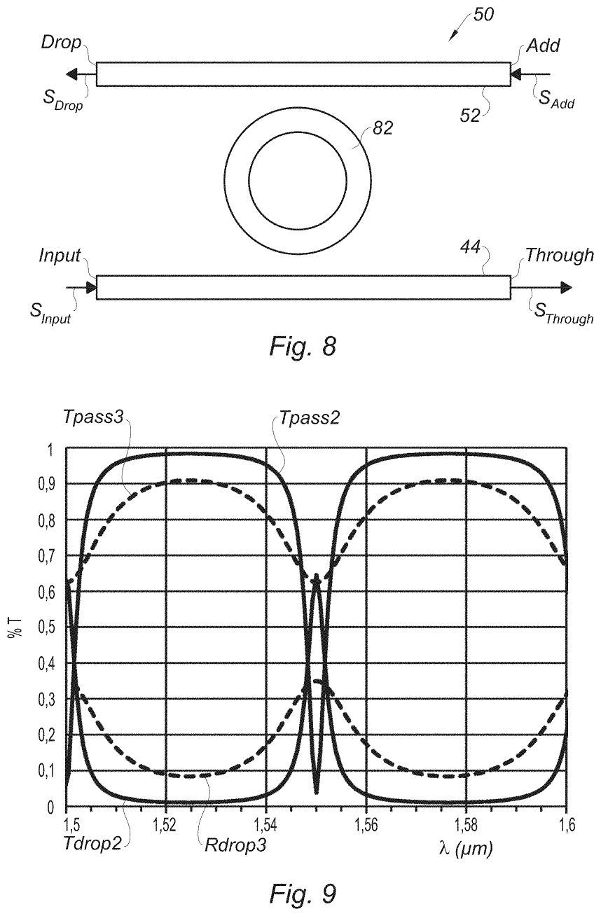

FIG. 8 shows an example of a coupler 50 corresponding to a ring microresonator comprising waveguides 44 and 52 having a third ring-shaped waveguide 82 arranged therebetween. Incident laser radiation S_{Input} is supplied at end Input of coupler 50 by main waveguide 44. Optical coupling phenomena between waveguides 44, 52, 82 may occur so that part of or the entire incident laser radiation S_{Input} may be deviated by ring 82 towards secondary waveguide 52. Incident laser radiation S_{Input} then divides into the laser radiation S_{Through} emitted at end Through of the coupler by main waveguide 44, and the laser radiation S_{Drop} emitted at end Drop of the coupler by secondary waveguide 52. A possible light signal S_{Add} received at the other end, called Add, of secondary waveguide 52, may also be deviated towards ends Through and Drop of the ring microresonator. In the present embodiment, signal S_{Add} is zero.

FIG. 9 shows, in full line, according to the incident wavelength of the laser, a curve of variation Tpass2 of the ratio of the power of radiation S_{Through} to the power of radiation S_{Input} and a curve of variation Tdrop2 of the ratio of the power of radiation S_{Drop} to the power of radiation S_{Input} for a coupling coefficient between main waveguide 44 and ring 82 equal to 0.9, for a coupling coefficient between secondary waveguide 52 and ring 82 equal to 0.9 and for a transmission coefficient in ring 82 equal to 0.95. FIG. 9 further shows, in dotted lines, according to the incident wavelength of the laser, a curve of variation Tpass3 of the ratio of the power of radiation S_{Through} to the power of radiation S_{Input} and a curve of variation Tdrop3 of the ratio of the power of radiation S_{Drop} to the power of radiation S_{Input} for a coupling coefficient between main waveguide 44 and ring 82 equal to 0.9, for a coupling coefficient between secondary waveguide 52 and ring 82 equal to 0.3, and for a transmission coefficient in ring 82 equal to 0.95. The coupling coefficients particularly depend on the intervals between ring 82 and waveguides 44 and 52. It is thus possible to select the proportion of the incident radiation S_{Input} which is deviated towards secondary waveguide 52.

FIG. 10 is a view similar to FIG. 7 of another embodiment of device 90. Device 90 comprises all the elements of the device 80 shown in FIG. 7, with the difference that each optical coupler 50 is a ring optical microresonator coupler of all-pass type.

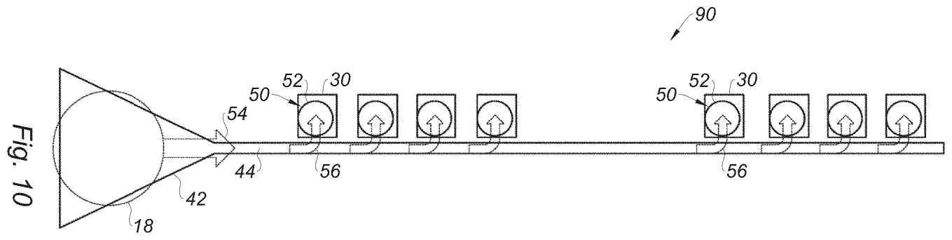

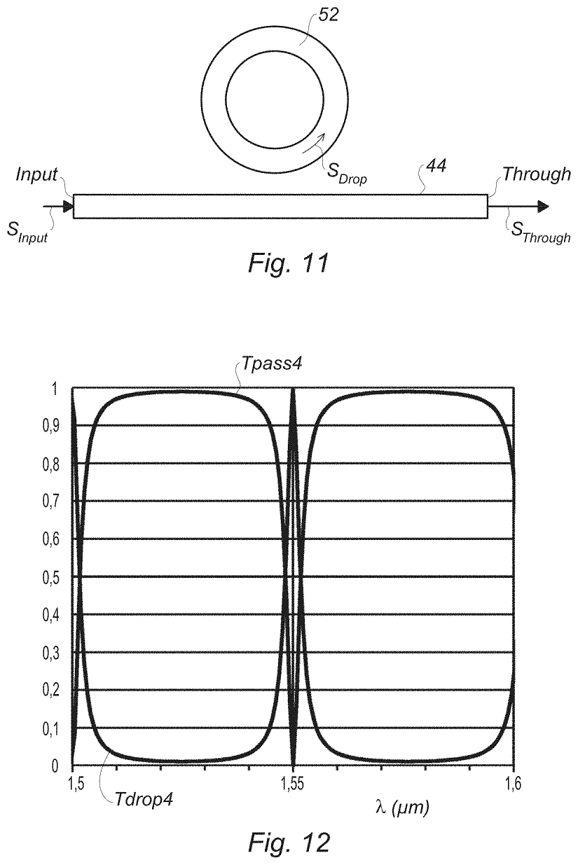

FIG. 11 shows an example of an all-pass type ring microresonator 50. This microresonator has the same structure as that shown in FIG. 8, with the difference that secondary waveguide 52 and ring 82 are confounded. In this case, ring 52 is located under absorbing region 28.

FIG. 12 shows, in full line, according to the incident wavelength of the laser, a curve of variation Tpass4 of the ratio of the power of radiation S_{Through} to the power of radiation S_{Input} and a curve of variation Tdrop5 according to the incident wavelength, of the ratio of the power of radiation S_{Drop} passing through ring 52 to the power of radiation S_{Input} for a coupling coefficient between main waveguide 44 and ring 52 equal to 0.9 and for a transmission coefficient in ring 52 equal to 0.85. The coupling coefficients particularly depend on the intervals between ring 82 and main waveguide 44. It is thus possible to select the proportion of the incident radiation S_{Input} which is deviated towards secondary waveguide 52.

FIG. 13 is a view similar to FIG. 10 of another embodiment of device 100. Device 110 comprises all the elements of the device 90 shown in FIG. 10 and further comprises, for each coupler 50, a device 102 for heating ring 52. Device 102 may comprise a ring-shaped resistive track placed in front of ring 52. Resistive track 112 emits more or less heat by Joule effect according to the intensity of the current which flows through resistive track 112. The coupling coefficient between ring 82 and main waveguide 44 particularly depends on temperature. It is thus possible to select the proportion of the incident radiation S_{Input} which is deviated towards secondary waveguide 52 by varying the quantity of heat generated by heating device 102. The control of heating devices 102 may be performed by a probe system.

An advantage of the previously-described embodiments is to be able to simultaneously detach a plurality of objects 30. This enables to decrease the duration of an operation of transfer of objects 30.

An advantage of the previously-described embodiments is that laser 18 points in a single location on support 22 to detach a plurality of objects 30. The control of the displacement of laser 18 is thus simplified.

Another advantage of the previously-described devices is that laser 18 cannot cross support 22, which enables not to use a support 22 transparent to laser 18.

Another advantage of the previously-described devices is that the object 30 to be detached is not placed in the line of sight of laser 18. This enables to decrease risks of deterioration of object 30 by laser 18.

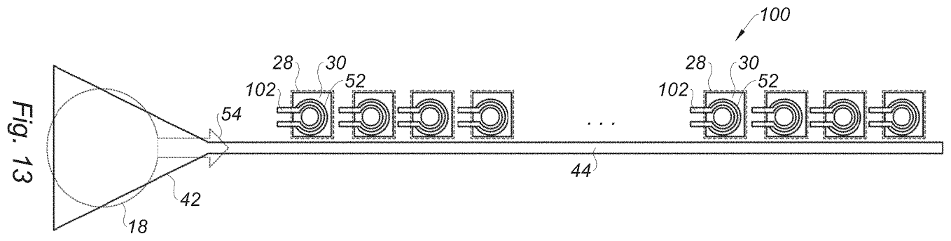

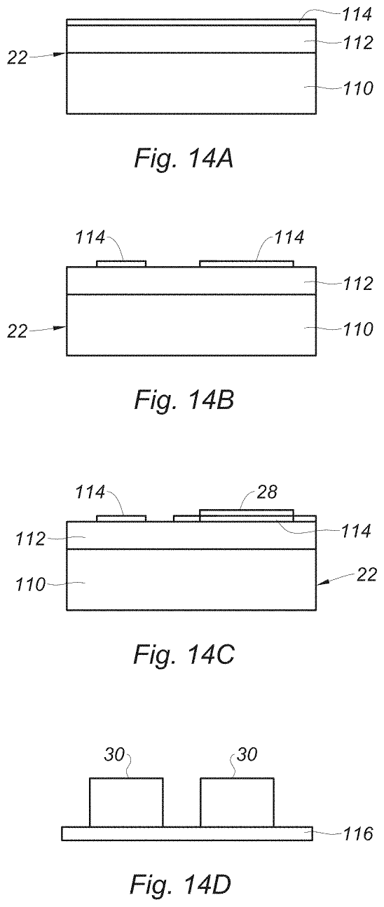

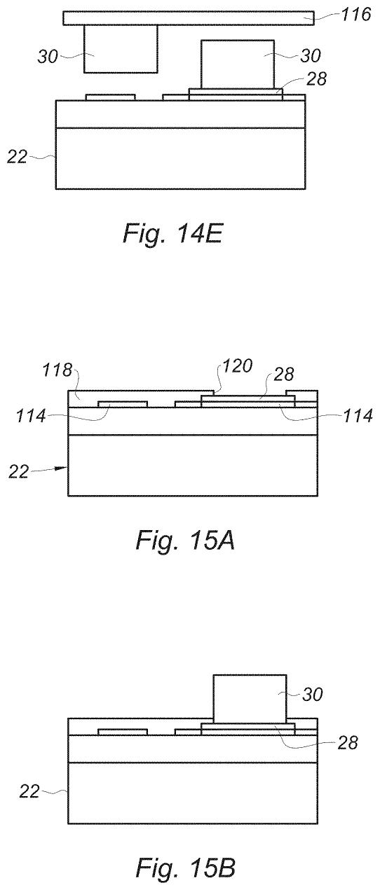

FIGS. 14A to 14E are partial simplified cross-section views of the structures obtained at successive steps of another embodiment of a method of manufacturing the device 40 shown in FIGS. 2 and 3.

FIG. 14A shows the support 22 corresponding to a SOI-type support comprising a stack of a substrate 110, of an insulating layer 112, and of a semiconductor layer 114. Insulating layer 112 is for example made of silicon oxide. Semiconductor layer 114 is for example made of silicon. The thickness of semiconductor layer 114 is for example in the range from 100 nm to 1,000 nm.

FIG. 14B shows the structure obtained after the etching of portions of semiconductor layer 114 to delimit, in semiconductor layer 114, waveguides 44 and 52 and couplers 42 and 50. This may implement lithography steps.

FIG. 14C shows the structure obtained after the forming of absorbing regions 28, a single absorbing region 28 being shown in FIG. 14C. This may comprise the deposition of a layer of the material forming absorbing regions 28 over the entire structure shown in FIG. 14B and the etching of portions of the layer to only keep absorbing regions 28.

FIG. 14D shows the structure obtained after the forming of objects 30 on a support 116. This step may be carried out independently from the steps previously described in relation with FIGS. 14A to 14C.

FIG. 14E shows the structure obtained after the transfer of at least some of the objects 30 from support 116 to support 22. An advantage of the embodiment described in relation with FIGS. 14A to 14B is that support 116 may be adapted to the forming of objects 30, for example, with a strong density of objects 30 per support 116, while support 22 is adapted to the transfer to the final support, that is, to the envisaged application.

FIGS. 15A and 15B are partial simplified cross-section views of the structures obtained at successive steps of another embodiment of a method of manufacturing the device 40 shown in FIGS. 2 and 3. The initial steps of the present embodiment are those previously described in relation with FIGS. 14A to 14C.

FIG. 15A shows the structure obtained after the deposition of an insulating layer 118 on the obtained structure shown in FIG. 14C and after the etching, for each object 30, of an opening 120 at least partly exposing absorbing region 28 at the desired location of object 30.

FIG. 15B shows the structure obtained after the forming of object 30 on absorbing region 28. According to an embodiment, object 30 comprises three-dimensional optoelectronic components, that is, optoelectronic components comprising three-dimensional semiconductor elements, in particular of micrometer-range or nanometer-range dimensions, and an active area formed on the surface of each three-dimensional element. The region from which most of the electromagnetic radiation supplied by the optoelectronic component is emitted or where most of the electromagnetic radiation received by the optoelectronic component is captured is called active area of the optoelectronic component. Examples of three-dimensional elements are microwires, nanowires, micrometer-range or nanometer-range conical elements, or micrometer-range or nanometer-range tapered elements.

Absorbing region 28 may be made of a material favoring the growth of three-dimensional elements. Absorbing region 28 may comprise a single seed layer favoring the growth of three-dimensional elements or a stack of layers, at least the upper level of which is a seed layer favoring the growth of three-dimensional elements.

According to an embodiment, the semiconductor elements are at least partly formed from at least one semiconductor material. The semiconductor material is selected from the group comprising III-V compounds, II-VI compounds, or group-IV semiconductors or compounds. The semiconductor elements may be at least partly formed from semiconductor materials mainly comprising a III-V compound, for example, a III-N compound. Examples of group-III elements comprise gallium (Ga), indium (In), or aluminum (Al). Examples of III-N compounds are GaN, AlN, InN, InGaN, AlGaN, or AlInGaN. Other group-V elements may also be used, for example, phosphorus or arsenic.

Absorbing region 28 may comprise a layer of a nitride, a carbide, or a boride of a transition metal from column IV, V, or VI of the periodic table of elements or a combination of these compounds. As an example, absorbing region 28 may at least partly be made of aluminum nitride (AlN), of aluminum oxide (Al₂O₃), of boron (B), of boron nitride (BN), of titanium (Ti), of titanium nitride (TiN), of tantalum (Ta), of tantalum nitride (TaN), of hafnium (Hf), of hafnium nitride (HfN), of niobium (Nb), of niobium nitride (NbN), of zirconium (Zr), of zirconium borate (ZrB₂), of zirconium nitride (ZrN), of silicon carbide (SiC), of tantalum carbide nitride (TaCN), of magnesium nitride in MgₓN_{y} form, where x is approximately equal to 3 and y is approximately equal to 2, for example, magnesium nitride in Mg₃N₂ form.

In the previously-described embodiments, after the transfer of objects 30 from support 22 to a final support, support 22 may be used again to perform a new transfer.

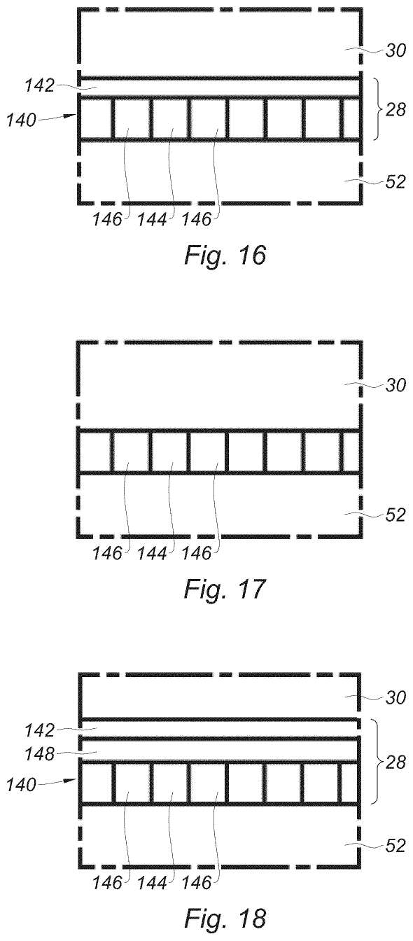

FIG. 16 is an enlarged view of another embodiment of the absorbing region 28 of device 40. According to the present embodiment, absorbing region 28 corresponds to the stacking of a layer of a photonic crystal 140 and of a layer 142 absorbing for the laser. According to an embodiment, photonic crystal layer 140 is interposed between secondary waveguide 52 and absorbing layer 142. According to an embodiment, a propagation mode of photonic crystal layer 140 corresponds to the wavelength of the laser. Preferably, photonic crystal layer 140 corresponds to a two-dimensional photonic crystal.

According to an embodiment, the thickness of absorbing layer 142 is in the range from 5 nm to 80 nm. The absorption of absorbing layer 142 for the laser is greater than 80%. According to an embodiment, absorbing layer 142 is made of a metal nitride, a semiconductor material, or a mixture of at least two of these compounds. According to an embodiment, the absorption coefficient k of absorbing layer 42 in the linear state for the wavelength of the laser is in the range from 1 to 10.

Photonic crystal layer 140 comprises a layer 144, called base layer hereafter, of a first material having a first refraction index at the wavelength of the laser where pillars 146 of a second material having a second refraction index at the wavelength of the laser extend. According to an embodiment, each pillar 146 extends substantially along a central axis perpendicular to surface 26 along a height L, measured perpendicularly to surface 26. Call “a” (pitch) the distance between the central axes of two adjacent pillars. According to an embodiment, each pillar 146 extends substantially across the entire thickness of base layer 144. Preferably, the first refraction index is smaller than the second refraction index. The first material may be transparent for laser 18. The first material may be a nitride or an oxide of a semiconductor compound such as silicon oxide (SiO₂), silicon nitride (SiN), or aluminum oxide (Al₂O₃). The second material may be transparent for the laser. The second material may be a nitride of a semiconductor compound, such as GaN, or a semiconductor compound, such as silicon (Si) or germanium (Ge). The thickness of photonic crystal layer 140 may be in the range from 0.1 μm to 3 μm.

FIG. 17 is an enlarged view of another embodiment of the absorbing region 28 of device 40. Absorbing region 28 comprises all the elements previously described for the embodiment illustrated in FIG. 16, with the difference that absorbing layer 142 is not present. The pillars 146 of photonic crystal layer 140 may be made of one of the materials previously described for absorbing layer 142. In this case, pillars 146 further play the role of absorbing layer 142 as will be described in further detail hereafter. As a variant, the base layer 144 of photonic crystal layer 140 is made of one of the materials previously described for absorbing layer 142. In this case, base layer 144 further plays the role of absorbing layer 142 as will be described in further detail hereafter.

FIG. 18 is an enlarged view of another embodiment of the absorbing region 28 of device 40. Absorbing region 28 comprises all the elements previously described for the embodiment illustrated in FIG. 16, with the difference that it further comprises at least one intermediate layer 148 interposed between photonic crystal layer 140 and absorbing layer 142. Intermediate 148 is transparent for the laser. According to an embodiment, intermediate layer 148 is made of a semiconductor material, for example, made of silicon (Si), of an oxide of a semiconductor, for example, of silicon oxide (SiO₂), or of a nitride of a semiconductor, for example, of silicon nitride (SiN). According to an embodiment, the thickness of intermediate layer 148 is in the range from 1 nm to 500 nm, preferably from 5 nm to 500 nm. As a variant, a stack of two layers or of more than two layers may be interposed between photonic crystal layer 140 and absorbing layer 142. In this case, each layer of the stack is transparent for the laser. According to an embodiment, the total thickness of the stack is in the range from 1 nm to 500 nm, preferably from 5 nm to 500 nm.

According to another embodiment of absorbing region 28, absorbing region 142 is not present and neither the material forming the pillars 146 of photonic crystal layer 140, nor the material forming the base layer 144 of photonic crystal layer 140 has an absorption coefficient k in the range from 1 to 10 at the wavelength of the laser in linear mode.

In the previously-described embodiments of absorbing region 28, the height L of each pillar 146 may be in the range from 0.1 μm to 3 μm. Preferably, pillars 146 are arranged in a grating. According to an embodiment, the pitch a between each pillar 146 and the closest pillar(s) is substantially constant.

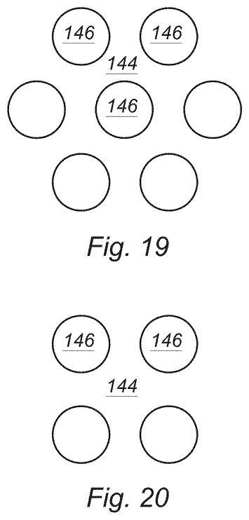

FIG. 19 is a partial simplified enlarged top view of an embodiment of photonic crystal layer 140 where pillars 146 are arranged in a hexagonal grating. This means that pillars 146 are, in the top view, arranged in rows, the centers of pillars 146 being at the apexes of equilateral triangles, the centers of two adjacent pillars 146 of a same row being separated by pitch a and the centers of the pillars 146 of two adjacent rows being shifted by distance a/2 along the row direction.

FIG. 20 is an enlarged partial simplified top view of an embodiment of photonic crystal layer 140 where pillars 146 are arranged in a square grating. This means that pillars 146 are arranged in rows and in columns, the centers of pillars 146 being at the apexes of squares, two adjacent pillars 146 of a same row being separated by pitch a and two adjacent pillars 146 of a same column being separated by pitch a.

In the embodiments illustrated in FIGS. 19 and 20, each pillar 146 has a circular cross-section of diameter D in a plane parallel to surface 26. In the case of a hexagonal grating arrangement or a square grating arrangement, diameter D may be in the range from 0.05 μm to 2 μm. Pitch a may be in the range from 0.1 μm to 4 μm.

In the embodiments illustrated in FIGS. 19 and 20, the cross-section of each pillar 146 in a plane parallel to surface 26 is circular. The cross-section of pillars 146 may however have a different shape, for example, the shape of an oval, of a polygon, particularly of a square, of a rectangle, of a hexagon, etc. According to an embodiment, all pillars 146 have the same cross-section.

In operation, laser beam 18 is preferably conveyed by secondary waveguide 52. The photonic crystal layer 140 of absorbing region 28 enables to increase the absorption of the laser radiation by absorbing region 28.

When absorbing region 28 comprises absorbing layer 142, photonic crystal layer 140 enables in particular to increase the absorption 1 of laser radiation 18 in absorbing layer 142. This enables to obtain the ablation of absorbing layer 142. When pillars 146 or base layer 144 is made of a material absorbing laser 18, photonic crystal layer 140 enables in particular to increase the absorption of the laser radiation in pillars 146 or in base layer 144. This enables to obtain the ablation of photonic crystal layer 140.

When absorbing layer 142 is not present, and neither the material forming the pillars 146 of photonic crystal layer 140, nor the material forming the base layer 144 of photonic crystal layer 140 has an absorption coefficient k in the range from 1 to 10 at the wavelength of the laser in linear mode, photonic crystal layer 140 enables to locally increase the density of energy in photonic crystal layer 140 and in the vicinity of photonic crystal layer 140. This enables to increase the absorption of the laser by non-linear absorption phenomena in photonic crystal layer 140 and in the vicinity of photonic crystal layer 140, which causes the ablation of photonic crystal layer 140. The presence of photonic crystal layer 140 then enables to decrease the intensity of the laser for which the non-linear absorption phenomena appear in photonic crystal layer 140 and/or in the vicinity of photonic crystal layer 40.

Various embodiments and variants have been described. Those skilled in the art will understand that certain features of these various embodiments and variants may be combined, and other variants will occur to those skilled in the art. In particular, the embodiment previously described in relation with FIG. 13 where each coupler 50 comprises a heating device 102 may be implemented with the embodiment previously described in relation with FIG. 7 to control the portion of the incident radiation which is deviated by coupler 50. Further, in the previously-described embodiments, a single secondary waveguide 52 extends under an absorbing region 28. As a variant, two secondary waveguides 52 or more than two secondary waveguides 52 may extend under a single absorbing region 28, for example, by emerging under absorbing region 28 according to different sides of absorbing region 28. This enables to increase the homogeneity of the absorption of laser 18 in absorbing region 28.

Finally, the practical implementation of the embodiments and variants described herein is within the capabilities of those skilled in the art based on the functional indications provided hereinabove.

1. Device configured for a laser treatment, comprising a support and objects, each attached to the support via a region absorbing for the laser, the support comprising a system for optically guiding the laser towards at least a plurality of said absorbing regions.

2. Device according to claim 1, wherein the optical guiding system comprises a surface optical coupler, adapted to capturing the laser.

3. Device according to claim 1, wherein the optical guiding system comprises a first waveguide for the laser and second waveguides for the laser, each second waveguide extending in front of one of the absorbing regions and being coupled to the first waveguide by an optical waveguide coupler.

4. Device according to claim 3, wherein the optical guiding system—comprises a surface optical coupler, adapted to capturing the laser, wherein the surface optical coupler is coupled to an end of the first waveguide.

5. Device according to claim 3, wherein each optical waveguide coupler is a multimode interference coupler or an evanescent wave optical coupler.

6. Device according to claim 3, wherein each optical waveguide coupler comprises a ring microresonator.

7. Device according to claim 3, wherein the optical waveguide couplers comprise at least first optical couplers configured to perform a coupling of a laser radiation at a first wavelength and not to perform a coupling of a laser radiation at a second wavelength different from the first wavelength and second optical couplers configured to perform a coupling of the laser radiation at the second wavelength and not to perform a coupling of a laser radiation at the first wavelength.

8. Device according to claim 3, wherein a plurality of the optical waveguide couplers each have a coefficient of coupling with the first waveguide which depends on temperature.

9. Device according to claim 8, further comprising systems for heating said plurality of optical waveguide couplers.

10. Device according to claim 3, further comprising a photonic crystal each object and one of the second waveguides.

11. Device according to claim 10, wherein the photonic crystal is a two-dimensional photonic crystal.

12. Device according to claim 10, wherein the photonic crystal comprises a base layer of a first material and a grating of pillars of a second material different from the first material, each pillar extending in the base layer across at least a portion of the thickness of the base layer.

13. Device according to claim 1, wherein each object comprises an electronic circuit.

14. Device according to claim 1, wherein the absorption of the region absorbing for the laser is greater than 60%.

15. Method of treatment with a laser of a device comprising a support and objects, each attached to the support via a region absorbing for the laser, the support comprising a system for optically guiding the laser towards at least a plurality of said absorbing regions, the method comprising the exposure to the laser beam of a portion of the optical guiding system.

16. Method according to claim 15, wherein the exposure to the laser beam of a portion of the optical guiding system is performed on the side of the support covered with the objects.

17. Method according to claim 15, comprising the attaching of a plurality of the objects to a substrate, the objects being still coupled to the support, and the simultaneous destruction of the absorbing regions attached to the objects of said plurality by the laser guided by the optical guiding system.

18. Method according to claim 17, wherein the optical guiding system comprises a first waveguide for the laser and second waveguides for the laser, each second waveguide extending in front of one of the absorbing regions and being coupled to the first waveguide by an optical waveguide coupler having a coefficient of coupling with the first waveguide.

19. Method according to claim 18, wherein each optical waveguide coupler has a coefficient of coupling with the first waveguide, the method comprising a step of modification of the coupling coefficients of a plurality of said optical waveguide couplers to select the objects of said plurality for which is performed the simultaneous destruction of the absorbing regions attached to the objects of said plurality by the laser guided by the optical guiding system.

20. Method according to claim 19, comprising a step of heating of said plurality of optical waveguide couplers.

21. Method according to claim 17, wherein the objects are distributed into first objects and second objects, the method comprising, at a first step, the simultaneous destruction of the absorbing regions attached to the first objects by the laser guided by the optical guiding system and, at a second step, the simultaneous destruction of the absorbing regions attached to the second objects by said laser, guided by the optical guiding system.

22. Method according to claim 21, wherein each optical waveguide coupler associated with one of the first objects allows the optical coupling between the first waveguide and the second waveguide coupled to said optical waveguide coupler when the laser is at a first wavelength and does not allow the optical coupling between the first waveguide and the second waveguide coupled to said optical waveguide coupler when the laser is at a second wavelength different from the first wavelength, and each optical waveguide coupler associated with one of the second objects allows the optical coupling between the first waveguide and the second waveguide coupled to said optical waveguide coupler when the laser is at the second wavelength and does not allow the optical coupling between the first waveguide and the second waveguide coupled to said optical waveguide coupler when the laser is at the first wavelength.
